(19) United States
(12) Patent Application Publication
(10) Pub. No.: US 2018/0187978 A1
(43) Pub. Date: Jul. 5, 2018

(54) FIN-DIFFUSER HEAT SINK WITH HIGH CONDUCTIVITY HEAT SPREADER

(71) Applicant: HAMILTON SUNDSTRAND CORPORATION, Charlotte, NC (US)

(72) Inventors: Neal R. Herring, East Hampton, CT (US); Ram Ranjan, Glastonbury, CT (US); Joseph Turney, Amston, CT (US); Charles E. Lents, Amston, CT (US); Subramanyaravi Annapragada, Shrewsbury, MA (US); Brian Eric St. Rock, Andover, CT (US)

(21) Appl. No.: 15/908,352

(22) Filed: Feb. 28, 2018

Related U.S. Application Data
(62) Division of application No. 14/194,306, filed on Feb. 28, 2014.
(60) Provisional application No. 61/870,907, filed on Aug. 28, 2013.

(51) Int. Cl. F28D 15/02; H01L 23/427; F28D 15/04

(52) U.S. Cl. CPC F28D 15/0208; F28D 15/0266; Y10T 29/49353; H01L 2924/0002; H01L 2924/00; H01L 23/427; F28D 15/0233; F28D 15/043; Y10T 29/4935

(57) ABSTRACT

A method and apparatus for cooling a heat source is disclosed. The apparatus includes a fin-diffuser including a blower integrated with fins of a diffuser. A heat spreader is coupled to the fin-diffuser. The heat spreader is configured to spread heat from a location proximate the blower to location of the fins. The apparatus spreads heat from a heat source proximate a blower of the fin-diffuser to a location away from the blower to cool the heat source.

### CROSS-REFERENCE TO RELATED APPLICATIONS

This application claims priority from U.S. Provisional Application Ser. No. 61/870,907, filed on Aug. 28, 2013 and U.S. Non-Provisional application Ser. No. 14/194,306, filed on Feb. 28, 2014, both of which are incorporated by reference herein in their entirety.

### BACKGROUND

Electronics devices may be air-cooled or liquid-cooled, depending on their applications. To facilitate packaging, electronics devices are typically contained within rectangular enclosures which are cooled using externally-located blowers and linear heat sinks that are readily compatible with rectangular plan-forms. In a typical enclosure, the spatial layout of various power electronics components result in highly non-uniform heat flux profiles that include hot spots that drive the sizing requirements of cooling equipment. An integrated fin-diffuser may be used to cool the electronics device. However, the air flow directly underneath a blower of the fin-diffuser is generally low, making the placement of a hot spot underneath the blower troublesome.

### SUMMARY

According to one embodiment of the present invention a method of cooling a heat source includes: coupling an integrated fin-diffuser to a heat spreader to form a cooling assembly; coupling the cooling assembly to the heat source; and spreading heat from the heat source generated proximate a blower of the fin-diffuser to a location away from the blower to cool the heat source.

According to another embodiment, an apparatus for cooling a heat source includes: a fin-diffuser comprising a blower integrated with fins of a diffuser; and a heat spreader coupled to the fin-diffuser, wherein the heat spreader is configured to spread heat from a location proximate the blower to location of the fins.

According to another embodiment, a cooling assembly includes: a fin-diffuser comprising a blower integrated with fins of a diffuser; and a heat spreader coupled to the fin-diffuser, wherein the heat spreader is configured to spread heat from a location proximate the blower to a location of the fins.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 shows an exemplary cooling assembly in one embodiment of the present invention;

FIG. 2 shows details of an exemplary heat spreader of the cooling assembly;

FIG. 3 shows an embodiment of a heat spreader with capillary wick heat pipes including an oscillating heat pipe;

FIG. 4 shows an alternative embodiment of a heat spreader that includes a radial oscillating heat pipe;

FIG. 5 shows the illustrative cooling assembly of FIG. 1 as used in another embodiment;

FIG. 6 shows a cooling assembly as used in another illustrative embodiment; and

FIG. 7 shows a three-dimensional heat spreading device for diffusing heat using the cooling assembly of the present invention.

### DETAILED DESCRIPTION

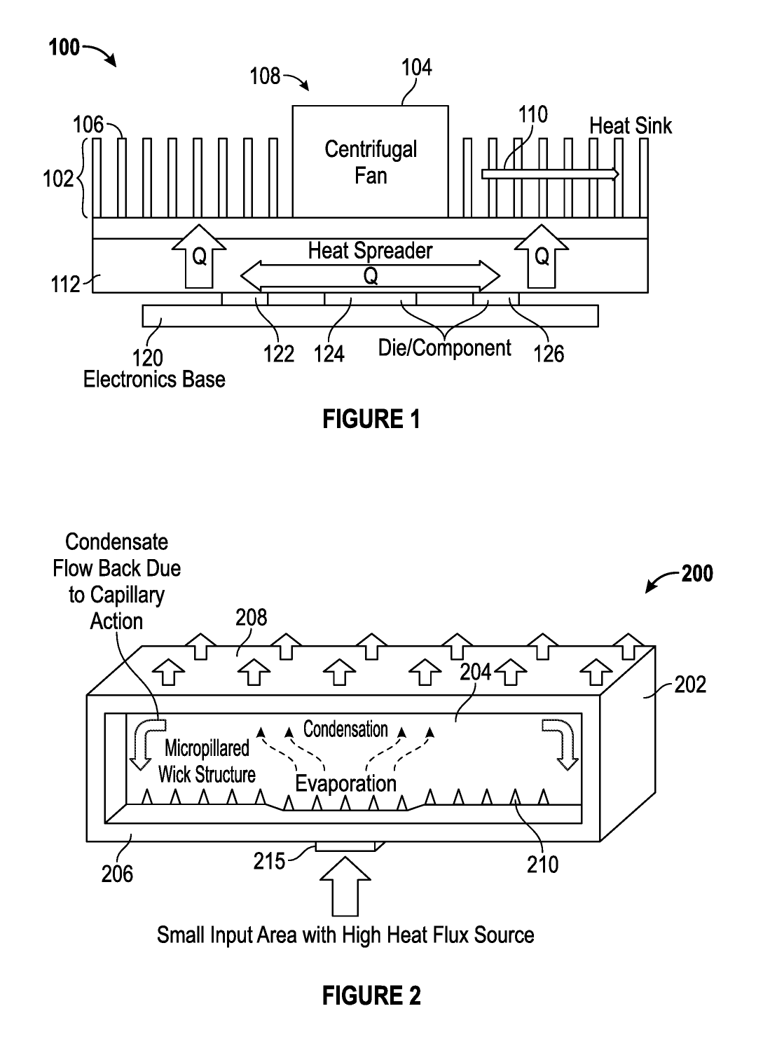

FIG. 1 shows an exemplary cooling assembly 100 in one embodiment of the present invention. The exemplary cooling assembly 100 includes a fin-diffuser 102 that includes a cooling fan or blower 104 that is integrated with diffuser fins 106. The integration of the blower 104 with the diffuser fins 106 generally places the blower 104 at a same level as the diffuser fins 106 rather than sitting on top of or below the diffuser fins 106. The blower 104 receives air from above the fin-diffuser 102 at inlet 108 and blows the air through the diffuser fins 106 in a generally radially-outward direction 110 through channels defined by the fins 106 to cool the fins 106. The fins 106 receive heat from a heat source such as electronics base 120. The air from the blower 104 therefore transfers the heat away from the fins 106 to cool the fins 106 and thereby to cool the electronics base 120.

Due to the design of the cooling assembly 100, with the blower 104 directing the air in a radially-outward direction 110, the air flow directly underneath the blower 104 is generally low. Consequently, heat transfer underneath the blower 104 is significantly lower than heat transfer in the channels of the diffuser fins 106. If the incoming heat flux from the heat source 120 is uniform over the entire base of the fin-diffuser 102, or worse, is concentrated underneath the blower 104, a significant and undesirable hot spot occurs underneath the blower 104. This may limit the use and placement of fin-diffuser heat sink to only certain configurations.

In order to reduce the development or effect of a hot spot below the blower 104 and to thereby enable heat sink placement irrespective of the heat source location, the present invention provides a heat spreader 112 coupled to a base of the fin-diffuser 102. The heat spreader 112 is configured to transfer heat from a location underneath the blower 104 to a relative extremity of the fin-diffuser 102 (i.e., the fins 106). Additionally, the heat spreader may provide uniform heat flux rejection to the base of fins given multiple concentrated heat sources. The magnitude of the hot spot is directly impacted by the thermal spreading capability of the heat spreader 112. Therefore, high thermal conductivity materials, such as copper, may be used in various embodiments. Other materials used in the heat spreader 112 have a high thermal conductivity which achieve an effective thermal conductivity >1000 W/mK.

Electronics base 120 is coupled to the heat spreader 112. The electronics base 120 includes several components 122, 124 and 126 that are local generators of heat. Component 124 is located directly underneath the blower 104. Heat spreader 112 therefore transfers heat from component 124 laterally to the diffuser fins 106, thereby improving an efficiency of the cooling assembly 100.

In addition to employing the thermal conductivity of the material to spread heat from the components 122, 124 and 126, a variety of passive, two-phase heat transfer devices can also be used to increase the thermal spreading, as discussed below with respect to FIG. 2-4. In other embodiments, the heat source may be remote from the cooling assembly 100 and heat from the heat source may be carried to the cooling assembly via one or more heat pipes or heat conductors.

FIG. 2 shows details of an exemplary heat spreader 200 of the cooling assembly. The exemplary heat spreader 200 includes a vapor chamber 202 which contains a working fluid 204 therein. The vapor chamber 202 includes a bottom surface 206 that is thermally coupled to heat source 215 and an upper surface 208 that is thermally coupled to the fin-diffuser 102 (see FIG. 1). For illustrative purposes, the heat source 215 is centrally located along the bottom surface 206 and is therefore beneath the blower 104 of the fin-diffuser 102. The working fluid 204 in the vapor chamber 202 is evaporated and/or boiled by the heat supplied at the bottom surface 206 by the heat source 215. The evaporated working fluid 204 rises to transfer the heat to upper surface 208. The working fluid 204 may then move laterally along the upper surface 208 to spread the heat along the upper surface 208, thereby spreading the heat from a location beneath the blower 104 one or more locations proximate the diffuser fins 106. In other words, the vapor chamber 202 spreads the heat from a small concentrated input area (i.e., heat source 215) over a large area (i.e., the area of the uppers surface 208) with substantially uniform heat flux distribution. The vapor chamber 202 may include a wick structure 210 which may be a micro-pillared wick structure, sintered copper particles, copper mesh or micropillars that facilitates a flow loop of the working fluid 204 inside the vapor chamber 202 during its evaporation and condensation.

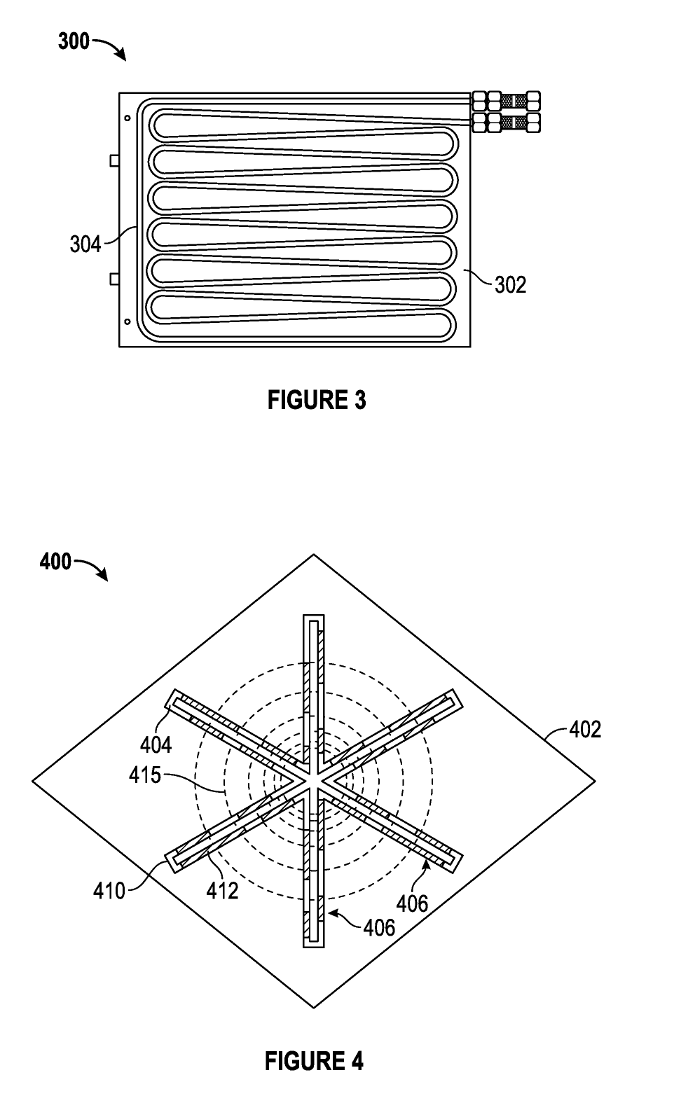

FIG. 3 shows an embodiment of a heat spreader 300 within capillary wick heat pipes including an oscillating heat pipe (OHP). The heat spreader 300 may include a thermally conductive material 302 and an integrated OHP 304. The integrated OHP 304 may be coupled to a surface of the thermally conductive material 302 or may be embedded within the thermally conductive material 302 in various embodiments. The oscillating heat pipe 304 generally includes a serpentine channel with capillary dimensions. A two-phase fluid, e.g., water and its vapor, is generally enclosed in the serpentine channel. Heating the channel at or near a heat source location causes the vapor phase of the fluid to expand, thus increasing pressure and to push the second phase of the fluid throughout the channels. Also, cooling the channel at or near the heat rejection surface causes the vapor phase pressure to reduce. The pressure fluctuations in the parallel channels lead to oscillations of the liquid and vapor phases, thus transferring heat from the heat source to the heat rejection surface through latent heat of the liquid phase and through spatial heat transport by oscillations.

FIG. 4 shows an alternative embodiment of a heat spreader 400 that includes a radial OHP 404. The radial OHP 404 may be integrated with a thermally conductive material 402 either via surface attachment or embedding, in various embodiments. The radial OHP 404 transfers heat according to the same physical mechanism described above with respect to FIG. 3. First phase 410 and second phase 412 of the fluid enclosed in the channel of the radial OHP 404 are shown in FIG. 4. The radial OHP 404 is designed so that the channel forms radial spokes 406. Therefore, heat may be spread from a central hot spot 415 to radial extremities of the heat spreader 400 via the radial OHP 404. In one aspect of the present invention, the OHP spokes 406 may be centered at hot spot 415. Referring back to FIG. 1, the radial OHP 404 may be disposed on the heat spreader 400 at a location underneath the blower 104. Alternately, the radial OHP 404 may be disposed at a location of the heat spreader 400 proximate a concentrated heat source, such as any of the components 122, 124 and 126, even at the components 122 and 126 that are off-center from the blower 104.

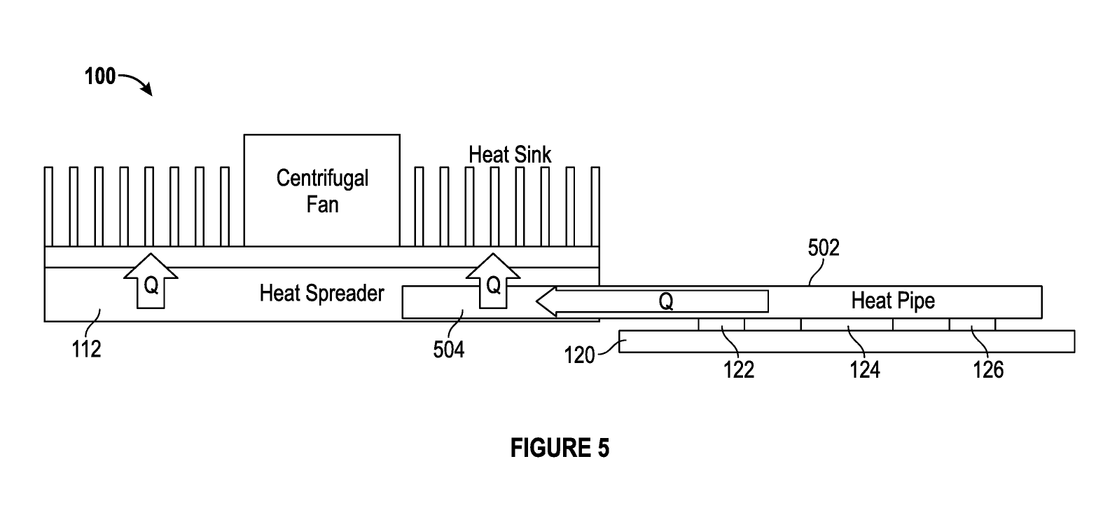

FIG. 5 shows the illustrative cooling assembly 100 of FIG. 1 as used in another embodiment. The cooling assembly Electronics base 120 is off to a side of the cooling assembly 100. The heat-generating components 122, 124 and 126 of the electronics base 120 are thermally coupled to a heat pipe 502 or other conductive material that transfers the heat to location 504 proximate the heat spreader 112 of the cooling assembly. The heat spreader diffuses the heat as discussed above.

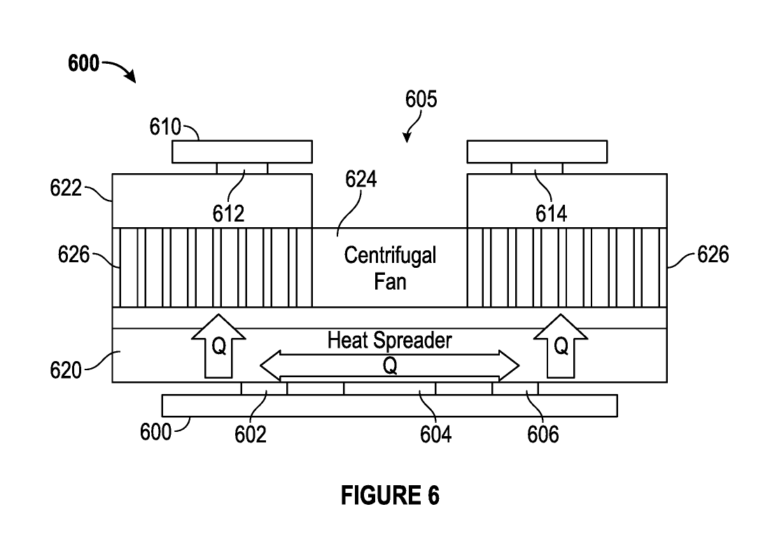

FIG. 6 shows a cooling assembly 600 as used in another illustrative embodiment. The blower 624 and diffuser fins 626 are sandwiched between heat spreaders 620 and 622. Electronics base 602 having heat-generating components 602, 604 and 606 are coupled to the heat spreader 620. Electronics base 610 having heat-generating components 612 and 614 are coupled to heat spreader 6122. An air vent 605 or suitable gap in the electronics base 610 allows air to be sucked into the blower 624 so that it can be circulated out through the diffuser fins. Thus, the cooling assembly 600 may perform cooling on of components on opposite sides of the blower 624 and diffuser fins 626.

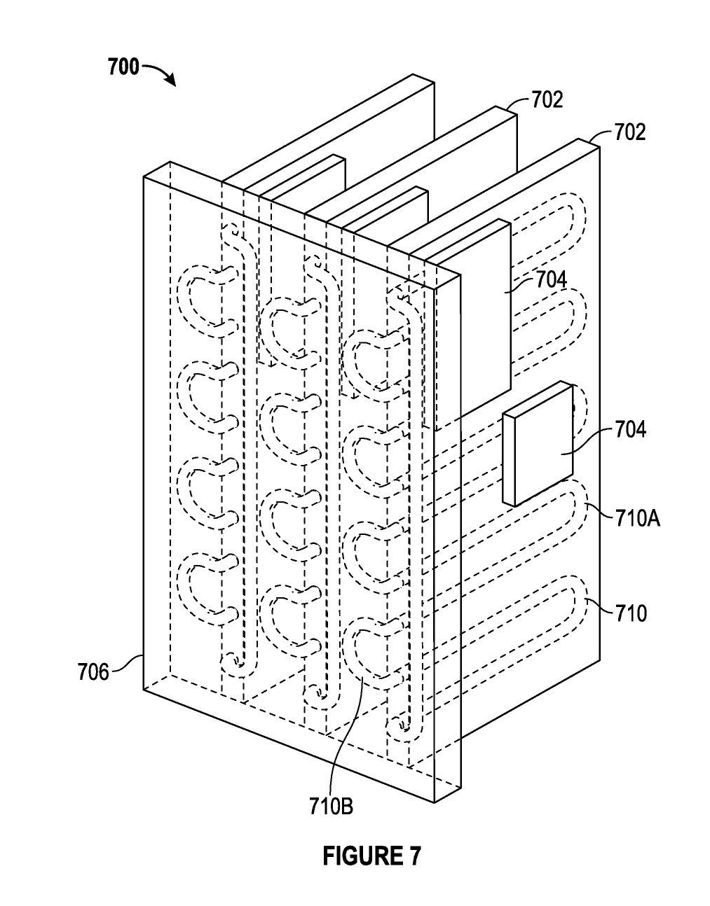

FIG. 7 shows a three-dimensional heat spreading device 700 for diffusing heat using the cooling assembly of the present invention. Electronic bases 702 include various heat-generating elements 704 therein. The electronic bases have oscillating heat pipes 710 integrated therein, such as the oscillating heat pipes described with respect to FIGS. 3 and 4 which provide a closed loop for the fluid flowing therein. In general, each electronic base 702 may have one heat pipe 710 therein. However, in other embodiments, more than one heat pipe may be enclosed in the electronic base 702. The oscillating heat pipe 710 may have segments 710a within the electronic base 702 and segments 710b that are in a plane at an angle to the electronic base. In one embodiment, segments 710b are substantially perpendicular to the segments 710a. The segments 710a direct heat in a direction normal to a surface of the of the heat spreader 706 in order to cool heat-generating elements 704 that are out of the plane of the heat spreader 706. The segments 710b are thermally coupled to a heat spreader 706. In turn, the heat spreader 706 is coupled to a blower and fin-diffuser assembly such as shown in FIG. 1. Therefore, a cooling assembly may be used to dissipate heat from heat-generating elements arranged in a three-dimensional structure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method of cooling a heat source, comprising:
coupling an integrated fin-diffuser to a heat spreader to form a cooling assembly;
coupling the cooling assembly to the heat source; and
spreading heat from the heat source generated proximate a blower of the fin-diffuser to a location away from the blower to cool the heat source.

2. The method of claim 1, wherein the heat spreader further comprises a vapor chamber for spreading the heat using a motion of working fluid in the vapor chamber.

3. The method of claim 2, wherein the working fluid transfers heat via an evaporation-condensation cycle.

4. The method of claim 1, wherein the heat spreader further comprises one o£ a capillary wick heat pipe; and an oscillating heat pipe.

5. The method of claim 4, wherein the oscillating heat pipe is one of: attached to a surface of the heat spreader, and embedded in the heat spreader.

6. The method of claim 4, wherein the oscillating heat pipe transfers heat away from the heat source along a radial direction.

7. The method of claim 4, wherein heat source further comprises a plurality of heat sources, further comprising coupling providing a plurality of oscillating heat pipes, with one of the plurality of oscillating heat pipes centered at one of the plurality heat sources.

8. An apparatus for cooling a heat source, comprising:
a fin-diffuser comprising a blower integrated with fins of a diffuser; and
a heat spreader coupled to the fin-diffuser, wherein the heat spreader is configured to spread heat from a location proximate the blower to a location of the fins.

9. The apparatus of claim 8, wherein the heat spreader further comprises one of:
a capillary wick heat pipe; and an oscillating heat pipe.

10. The apparatus of claim 9, wherein the oscillating heat pipe is one of: attached to a surface of the heat spreader, and embedded in the heat spreader.

11. The apparatus of claim 9, wherein the oscillating heat pipe transfers heat away from the heat source along a radial direction.

12. The apparatus of claim 9, further comprising a plurality of oscillating heat pipes located on the heat spreader at locations configured to coincide with locations of a plurality of heat sources.

13. A cooling assembly, comprising:
a fin-diffuser comprising a blower integrated with fins of a diffuser; and
a heat spreader coupled to the fin-diffuser, wherein the heat spreader is configured to spread heat from a location proximate the blower to a location of the fins.

14. The cooling assembly of claim 13, wherein the heat spreader further comprises one of: a capillary wick heat pipe; and an oscillating heat pipe.

15. The cooling assembly of claim 14, wherein the oscillating heat pipe is one of: attached to a surface of the heat spreader, and embedded in the heat spreader.
